(19) United States
(12) Patent Application Publication
(10) Pub. No.: US 2025/0275206 A1
(43) Pub. Date: Aug. 28, 2025

(54) PLASMA-FREE ETCHED B-GA2O3-NIO MERGED PIN SCHOTTKY DIODE WITH HIGH-VOLTAGE STRESS RELIABILITY

(71) Applicant: The Government of the United States of America, as represented by the Secretary of the Navy, Arlington, VA (US)

(72) Inventors: Joseph A. Spencer, Springfield, VA (US); Marko J. Tadjer, Vienna, VA (US); Alan G. Jacobs, Rockville, MD (US); Karl D. Hobart, Alexandria, VA (US); Yuhao Zhang, Blacksburg, VA (US); Neeraj Napal, Woodbridge, VA (US)

(73) Assignee: The Government of the United States of America, as represented by the Secretary of the Navy, Arlington, VA (US)

(21) Appl. No.: 19/059,801

(22) Filed: Feb. 21, 2025

Related U.S. Application Data
(60) Provisional application No. 63/556,985, filed on Feb. 23, 2024.

(51) Int. Cl. H10D 62/82; H10D 8/01; H10D 8/60; H10D 62/10

(52) U.S. Cl. CPC H10D 62/8271; H10D 8/051; H10D 8/60; H10D 62/105

(57) ABSTRACT

A (Ga₂O₃)-nickel oxide (NiO) heterojunction device and method of making the same are presented. In implementations, the method includes: providing a Ga₂O₃ base including a Ga₂O₃ substrate with an n-type Ga₂O₃ epitaxial layer thereon; forming NiO-filled internal trenches and an NiO-filled peripheral trench in the n-type Ga₂O₃ epitaxial layer using a plasma-free etching process; forming at least one junction termination extension (JTE) structure about the periphery of the n-type Ga₂O₃ epitaxial layer; depositing an anode over the NiO filled interior trenches, over portions of the NiO-filled peripheral trench, and over portions of the JTE structure; and depositing a cathode over a bottom surface of the Ga₂O₃ substrate, thereby forming the Ga₂O₃—NiO heterojunction device, wherein the Ga₂O₃—NiO heterojunction device is formed without the use of plasma-etching and is free of plasma-etching damage.

### FEDERALLY SPONSORED RESEARCH AND DEVELOPMENT

The United States Government has ownership rights in this invention. Licensing inquiries may be directed to Office of Technology Transfer, US Naval Research Laboratory, Code 1004, Washington, D.C. 20375, USA; +1.202.767.7230; nrltechtran@us.navy.mil, referencing Navy Case No. 212024-US2.

### BACKGROUND OF THE INVENTION

Aspects of the present invention relate generally to semiconductor devices and, more particularly, to a plasma-etch-free method of making a gallium oxide (Ga₂O₃)-nickel oxide (NiO) heterojunction device.

The stable beta (β) phase of Ga₂O₃ has received significant interest due to its scalable melt growth and properties favorable for high power electronics, such as an ultra-wide bandgap (UWBG) of 4.8 electron volt (eV), controllable donor doping across a wide range (10¹⁴-10²¹ cm⁻³), and a high critical breakdown electric field (6-8 megavolts). Ga₂O₃ is also the only wide bandgap (WBG) or UWBG semiconductor that can be grown from a melt; offering potential cost advantages over silicon carbide (SiC) and gallium nitride (GaN). Substrate and epitaxial growth technology for Ga₂O₃ is advancing rapidly, and 100 millimeter (mm) epitaxial wafers (epiwafers) are currently commercially available. As the field of high-power electronics continues to expand, Ga₂O₃ has shown promise as a candidate semiconductor for the next generation of power electronics.

The advantages mentioned above make Ga₂O₃ a candidate for vertical power rectifiers such as Schottky barrier (SBD) and trench Schottky diodes. These diodes are unipolar devices utilizing high quality n⁻ drift layers. On the other hand, PN diodes, junction barrier Schottky (JBS) diodes, and merged PiN Schottky (MPS) diodes are bi-polar devices relying on both electrons and holes to carry charge across an abrupt PN junction. This poses an issue for Ga₂O₃ where p-type conductivity has yet to be realized by means of either growth or implantation of acceptor species.

One approach to realize Ga₂O₃ bi-polar devices proposes the use of anisotype heterojunctions. Sputtered p-type NiO with a band gap of 3.7 eV and a favorable band offset to Ga₂O₃ has thus far been the most researched p-type semiconductor due to case of deposition and tunable acceptor concentration. Ga₂O₃—NiO PN diodes are fabricated by sputtering NiO atop a planar Ga₂O₃ drift layer, while the Ga₂O₃ NiO JBS and MPS diodes, identical in architecture, are further complicated by the need to embed the array of heterojunctions into the drift layer using various etch techniques. More mature, bi-polar WBG semiconductors such as SiC and GaN are not plagued with this issue as selective p-type implantation has been demonstrated with aluminum (Al) and magnesium (Mg), respectively. Patterned formation of Ga₂O₃—NiO heterojunctions introduces a host of issues yet to be addressed in the literature. Many works have studied Ga₂O₃ plasma etch damage, post etch treatments for damage recovery, and their impact on device performance. However, this issue is not quantified in studies involving etched Ga₂O₃—NiO heterojunctions. Recently, a plasma-free low-damage Ga₂O₃ etching technique using atomic Ga flux was demonstrated and applied in Ga₂O₃ trench Schottky barrier diodes. Compared to a Schottky diode, a junction-barrier Schottky (JBS) or a merged p-i-n Schottky (MPS) diode can offer reduced reverse leakage current and increased breakdown voltage, which makes these devices more practical from a commercialization standpoint.

Accordingly, there remains a need for Ga₂O₃ bi-polar devices, also known as bipolar junction transistors. In implementations of the invention discussed herein, we have demonstrated that the combination of a plasma-free Ga₂O₃ etch, a p-type NiO layer, and a high work function metal oxide layer (e.g., PtOx), which acts also as an Ohmic contact to the p-NiO layer, can result in improvement of both forward and reverse bias characteristics of a rectifier.

### SUMMARY OF THE INVENTION

In a first aspect of the invention, there is a method of making a gallium oxide (Ga₂O₃)-nickel oxide (NiO) heterojunction device including: providing a Ga₂O₃ base including a Ga₂O₃ substrate with an n-type Ga₂O₃ epitaxial layer thereon; forming NiO-filled internal trenches and an NiO-filled peripheral trench in the n-type Ga₂O₃ epitaxial layer using a plasma-free etching process; forming at least one junction termination extension (JTE) structure about the periphery of the n-type Ga₂O₃ epitaxial layer; depositing an anode over the NiO filled interior trenches, over portions of the NiO-filled peripheral trench, and over portions of the JTE structure; and depositing a cathode over a bottom surface of the Ga₂O₃ substrate, thereby forming the Ga₂O₃—NiO heterojunction device, wherein the Ga₂O₃—NiO heterojunction device is formed without the use of plasma-etching and is free of plasma-etching damage. In embodiments, internal trenches in the n-type Ga₂O₃ epitaxial layer are formed via the plasma-free etching process; a peripheral trench is formed about the periphery of the n-type Ga₂O₃ epitaxial layer via the plasma-free etching process; and p-type NiO is deposited into the internal trenches and the peripheral trench, thereby forming the NiO-filled internal trenches and an NiO-filled peripheral trench.

In implementations, forming the JTE structure includes: depositing the at least one JTE structure over portions of the NiO filled peripheral trench and surface portions of the Ga₂O₃ epitaxial layer. In embodiments, the Ga₂O₃—NiO heterojunction device is a merged PiN Schottky (MPS) diode having a specific contact resistance between the anode and the NiO of less than 0.0005 Ohm*cm². In aspects of the invention, the JTE structure comprises a bi-layer JTE structure including first and second layers of NiO. In implementations, depositing the JTE structure includes: depositing a first layer of NiO via sputtering in a pure argon atmosphere over portions of the peripheral NiO-filled trench and over portions of a surface of the Ga₂O₃ epitaxial layer; depositing a first stage of a second layer of NiO in 20:1 argon:oxygen atmosphere over the first layer and portions of the peripheral NiO-filled trench; and depositing a second stage of the second layer of NiO in a 2:1 argon:oxygen atmosphere over the first stage of the second layer of NiO and portions of the peripheral NiO-filled trench. In embodiments, the JTE structure comprises a layer of NiO. In implementations, forming the NiO-filled internal trenches and the NiO-filled peripheral trench in the n-type Ga₂O₃ epitaxial layer utilizes a plasma-free etching process comprises patterning using photolithography and gallium flux etching. The method may further include annealing the Ga₂O₃—NiO heterojunction device. The anode and cathode may comprise platinum oxide and gold. In implementations, the n-type Ga₂O₃ epitaxial layer is doped with silicon (Si).

In another aspect of the invention, there is a gallium oxide (Ga₂O₃)-nickel oxide (NiO) heterojunction device including: a Ga₂O₃ base comprised of a Ga₂O₃ substrate with an n-type Ga₂O₃ epitaxial layer thereon, the n-type Ga₂O₃ epitaxial layer including a plurality of NiO-filled internal trenches and an NiO-filled peripheral trench; a junction termination extension (JTE) structure formed about the periphery of the n-type Ga₂O₃ epitaxial layer; an anode formed over the NiO filled interior trenches, over portions of the NiO-filled peripheral trench, and over portions of the JTE structure; and a cathode formed over a bottom surface of the Ga₂O₃ substrate, wherein the Ga₂O₃—NiO heterojunction device is formed without the use of plasma-etching and is free of plasma-etching damage. In implementations, the JTE structure is a NiO bi-layer JTE structure. In embodiments, the first layer of the NiO bi-layer JTE structure extends beyond opposing edges of the anode. In aspects of the invention, the JTE structure comprises a layer of NiO. The anode and cathode may be made of platinum oxide and gold.

In embodiments, the JTE structure is formed over portions of the NiO filled peripheral trench and surface portions of the Ga₂O₃ epitaxial layer. In aspects of the invention, the Ga₂O₃—NiO heterojunction device is a merged PiN Schottky (MPS) diode having a specific contact resistance between the anode and the NiO of less than 0.0005 Ohm*cm². In embodiments, the n-type Ga₂O₃ epitaxial layer is doped with silicon (Si). In some implementations, the n-type Ga₂O₃ epitaxial layer has a thickness of at least 5 microns.

### BRIEF DESCRIPTION OF THE DRAWINGS

Aspects of the present invention are described in the detailed description which follows, in reference to the noted plurality of drawings by way of non-limiting examples of exemplary embodiments of the present invention.

FIG. 1 shows a flowchart of an exemplary method for making a semiconductor device in accordance with aspects of the present invention.

FIG. 2A depicts a stage of a device of the present invention including a SiO₂-patterned mask with interior trenches and a peripheral trench formed therein.

FIG. 2B depicts a stage of a device of the present invention after Ga flux etching.

FIG. 2C depicts a stage of a device of the present invention after the residual portions of the SiO₂ mask are removed.

FIG. 2D depicts a stage of a device of the present invention with NiO-filled interior trenches and an NiO-filled peripheral trench.

FIG. 2E depicts a Ga₂O₃—NiO heterojunction device of the present invention with opposing NiO JTEs portions and an anode and cathode.

FIG. 2F is a close-up partial view of FIG. 2F, showing the two stages of the second bi-layer of the NiO JTE structure.

FIG. 2G depicts another Ga₂O₃—NiO heterojunction device of the present invention with opposing NiO JTE portions and an anode and cathode.

FIG. 2H is a top view of the embodiment 200G of FIG. 2G.

FIG. 3A is a chart depicting C-V measurements of a PtOx and Ni SBD in accordance with embodiments of the invention

FIG. 3B is a chart depicting C-V measurements of a PtOx JBS diode in accordance with embodiments of the invention, showing a dual sweep at 300 kHz measured from accumulation to depletion (dashed line) and back to accumulation (solid line).

FIG. 3C is a chart depicting linear transmission line measurements of Ni and PtOx Ohmic contacts to NiO. Control films of NiO were isolated via lift-off on sapphire substrates, as indicated in FIG. 3C.

FIG. 4A is a chart depicting C-V measurements for a PtOx MPS and Ni JBS diodes in accordance with embodiments of the invention.

FIG. 4B is a chart depicting C-V measurements Ni/Au and PtOx/Au SBDs in accordance with embodiments of the invention, showing a dual sweep at 300 kHz measured from accumulation to depletion and back to accumulation.

FIG. 5 illustrates a testing waveform for high voltage reliability measurements in accordance with embodiments of the invention.

FIG. 6 is a chart depicting specific on-resistance and reverse leakage current as a function of stress time measured at 600, 700 and 800 V.

FIG. 7 is a chart depicting forward J-V measurements (25 curves) taken during the reliability measurements of the MPS diode at 700V.

### DETAILED DESCRIPTION

Aspects of the present invention relate generally to semiconductor devices and, more particularly, to a plasma-free etching method of making a gallium oxide (Ga₂O₃)-nickel oxide (NiO) heterojunction device. In embodiments, a method of fabricating a beta-gallium oxide (β-Ga₂O₃)—NiO merged PiN Schottky (MPS) diode is provided, which uses a gallium (Ga) flux plasma-free etch process and platinum oxide (PtOx) contacts. In general, an MPS diode is a hybrid device that combines a Schottky diode and a P-N diode in parallel.

Dry etching or plasma etching is a process of removing material, typically a masked pattern of semiconductor material, by exposing the material to a bombardment of ions (e.g., a plasma of nitrogen, chlorine, and boron trichloride), that dislodge particles of the material from the exposed surface. One drawback of plasma etching is the problem of surface damage that may result from the etching process, which can hinder device performance by increasing the level of leakage current (i.e., the amount of current that flows when it should not). For example, a high power (typically 600-1000 W) boron trichloride (BCl₃) reactive-ion etching (RIE) or inductively-coupled plasma (ICP) etching has long been known to negatively impact Ga₂O₃ surfaces and requires mitigation with high temperature or aggressive chemical treatments. While instances of plasma damage to Ga₂O₃ surfaces and Schottky contact formations are readily found within the literature, the impacts on a Ga₂O₃ NiO etched heterojunction remain a void.

Advantageously, the use of a plasma-free etch process in implementations of the invention avoids the problem of Ga₂O₃ surface damage that would be caused by a high-power plasma etch process. By removing the need for RIE plasma etching and post etch chemical treatments, embodiments of the invention provide a high quality and damage free surface for heterojunction formation.

In embodiments, PtOₓ acts as both a Schottky contact to n-type Ga₂O₃ as well as an Ohmic contact to p-type NiO. Compared to Ni contacts to NiO (Ni/NiO contacts) used in Ga₂O₃ junction barrier Schottky (JBS) diodes and PN diodes, the PtOₓ/NiO contact in accordance with embodiments of the invention exhibits a lower contact resistance as shown by linear transmission line measurements. This improved contact resistance enables an apparent second turn-on, potentially due to minority carrier injection, and a further decrease in differential on-resistance under forward diode operation, confirming the formation of a Ga₂O₃ MPS diode.

MPS diodes fabricated in accordance with embodiments of the invention were subjected to high reverse bias reliability testing. At 800 volts (V), MPS diodes were stressed for a cumulative time of 2000 seconds(s) while periodically switching the device on. No variation or degradation of the on-state performance was observed as the Schottky regime (<3 V) of the MPS diode was turned on. This signifies an improved Ga₂O₃ NiO heterojunction with minimal side-wall trapping as a result of the plasma-etch-free process.

### Exemplary Method

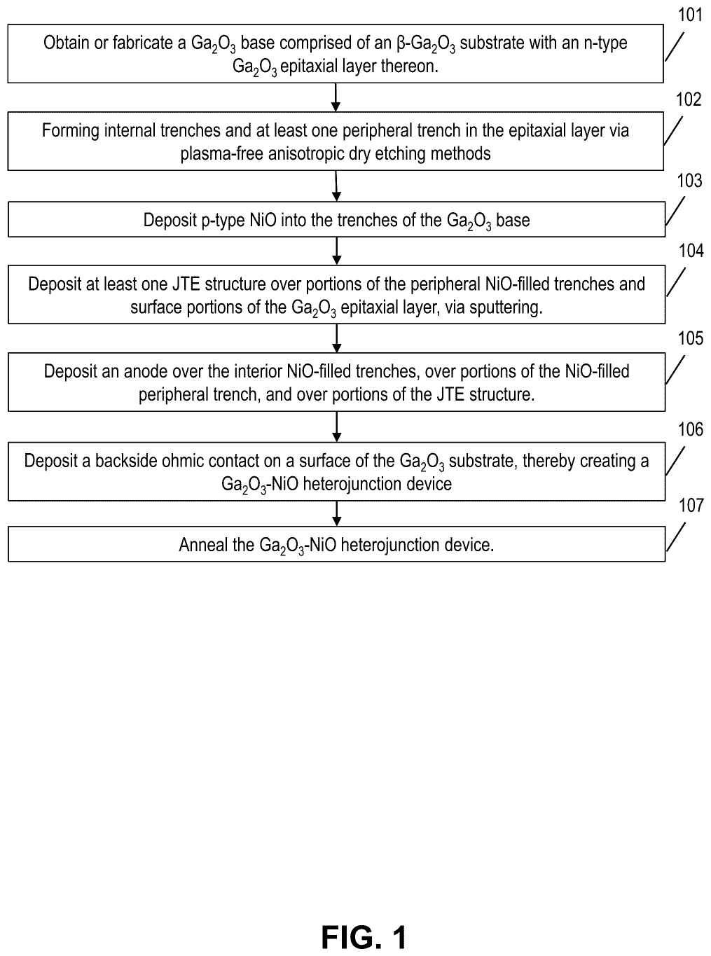

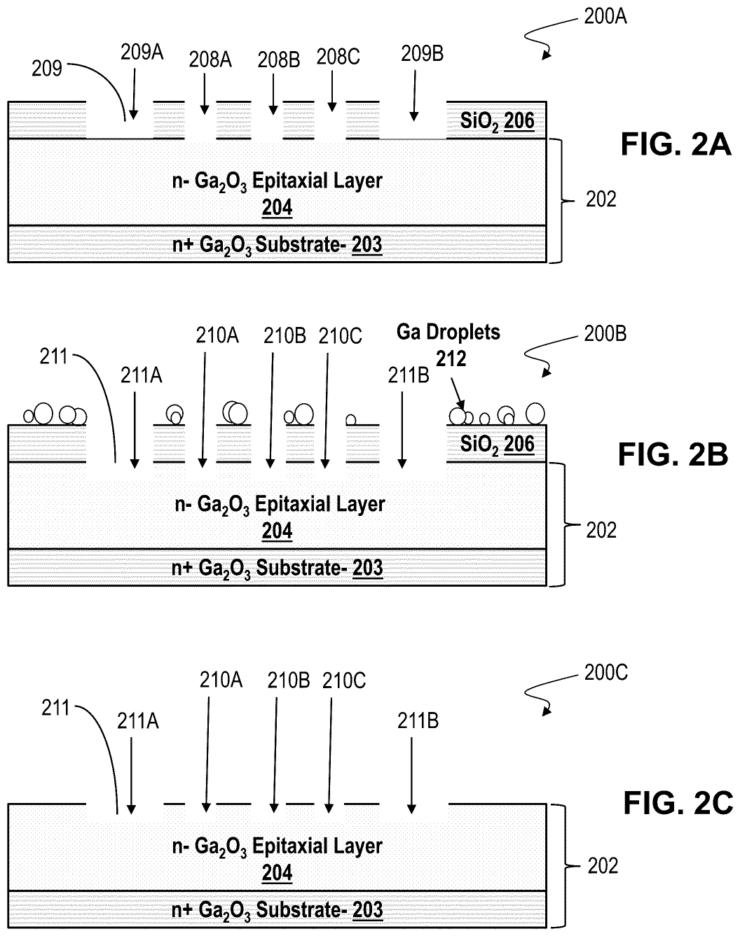

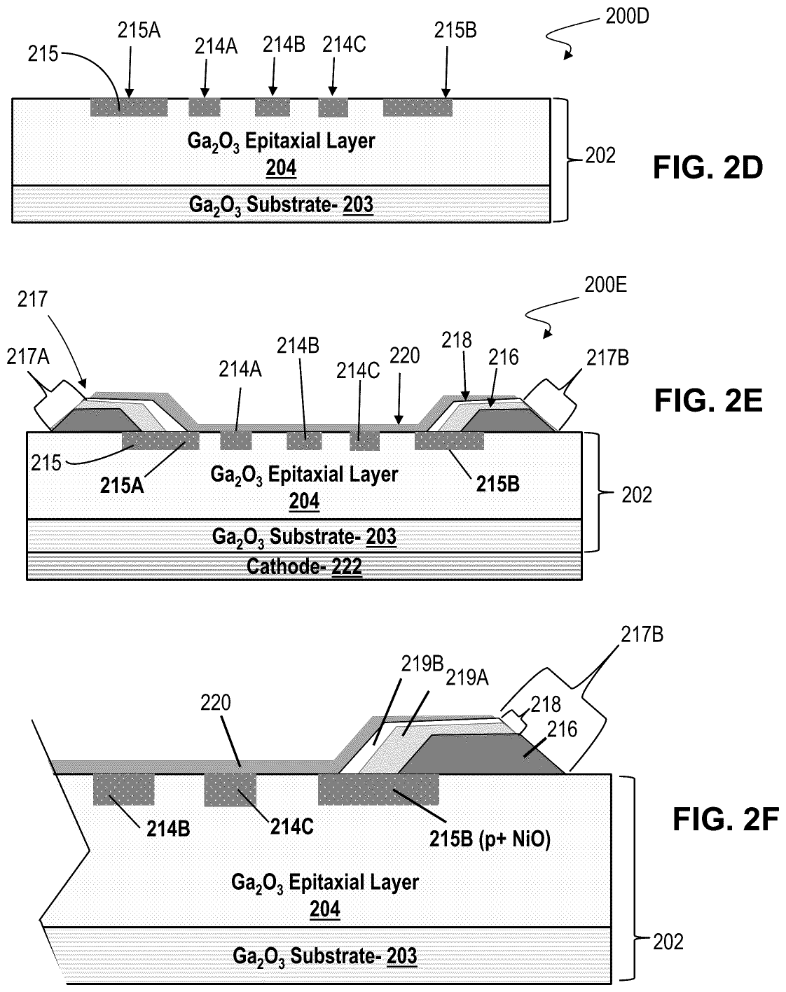

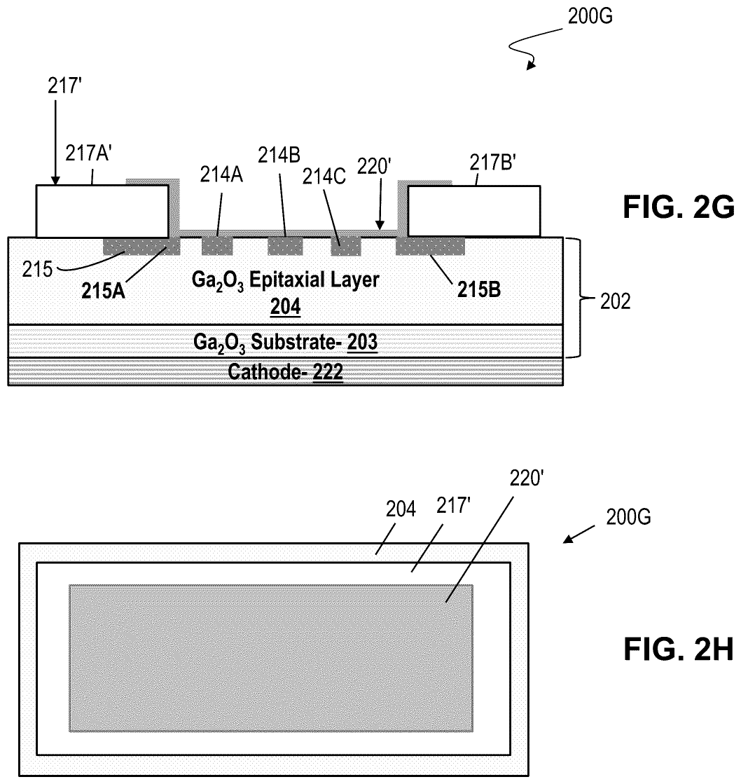

FIG. 1 shows a flowchart of an exemplary method for making a semiconductor device in accordance with aspects of the present invention. The method references semiconductor device elements depicted in FIGS. 2A-2F.

At 101, a gallium oxide (Ga₂O₃) base 202 is provided or fabricated, wherein the Ga₂O₃ base 202 is comprised of an n⁺ beta (β)-phase Ga₂O₃ substrate 203 with an n Ga₂O₃ epitaxial layer 204 grown thereon. See FIG. 2A described below. In embodiments, the substrate 203 is a tin (Sn)-doped β-Ga₂O₃ (β-Ga₂O₃:Sn) substrate with a halide vapor phase epitaxial (HVPE) layer 204 thereon. In implementations, the β-Ga₂O₃:Sn substrate has a thickness of 5 micrometers (μm), and includes unintentional silicon (Si) doping.

At 102, multiple internal trenches (e.g., 210A, 210B, 210C) and at least one peripheral trench 215 (hereafter the peripheral trench) are formed in the n-type Ga₂O₃ epitaxial layer 204 via a plasma-free anisotropic dry etching method. In embodiments, the trenches are formed using photolithographic gallium flux etching. In implementations, the peripheral trench 215 extends about the periphery of the Ga₂O₃ epitaxial layer 204. Opposing portions 215A and 215B of a single peripheral trench 215 are depicted in FIG. 2D discussed below, for example.

In one exemplary embodiment, a silicon oxide (SiO₂) mask layer 206 is deposited onto a surface of the Ga₂O₃ epitaxial layer 204 using plasma enhanced chemical vapor deposition (PECVD). Existing PECVD methods may be utilized to deposit the SiO₂ mask layer 206. The SiO₂ mask layer 206 is then patterned using a buffered oxide etchant (BOE), thereby generating a SiO₂-patterned surface of the Ga₂O₃ epitaxial layer 204. Existing patterning methods may be utilized to implement step 103. In embodiments, the patterning results in interior trenches 208A-208C formed in the SiO₂ mask, as well as the peripheral trench 215. See FIG. 2A discussed below. The SiO₂-patterned surface of the Ga₂O₃ base 202 is heat-cleaned. In implementations, the heat cleaning is performed for ten (10) minutes at 800 degrees Celsius (° C.). Existing heat cleaning methods may be utilized. See FIG. 2A discussed below.

FIG. 2A is a cross-sectional side view of a stage 200A of a device of the present invention including a SiO₂-patterned mask 206, with the interior trenches 208A-208C and a peripheral trench 209 formed therein. Opposing portions of the peripheral trench 209 are shown at 209A and 209B. The device stage 200A includes the Ga₂O₃ base 202 comprised of the n+ beta (β)-phase Ga₂O₃ substrate 203 with the n⁻ Ga₂O₃ epitaxial layer 204 grown thereon. While three interior trenches 208A-208C are depicted, it should be understood that more or less interior trenches may be formed in accordance with embodiments of the invention.

As part of the exemplary photolithography process of step 102, Ga flux etching of the SiO₂-patterned surface 206 of the Ga₂O₃ base is performed, resulting in an etched n Ga₂O₃ epitaxial layer 204, included interior trenches 210A-210C, and a peripheral trench 211 (opposing sides of which are shown at 211A and 211B). See FIG. 2B discussed below. In general, Ga flux etching is a technique that uses Ga to etch the surface of Ga₂O₃ and other materials. Ga flux etching uses molecular beam epitaxy (MBE) and other processes known to those skilled in the art. In implementations, the Ga flux etching is performed for 159 minutes (min) using ˜1.24×10⁻⁷ Torr of Ga flux at 725° C. thermocouple temperature in an MBE reactor maintained at 1×10⁻⁹ Torr during the etching.

FIG. 2B is a cross-sectional side view of a stage 200B of a device of the present invention after the Ga flux etching. Ga flux etching results in the interior trenches 210A-210C and the peripheral trench 211 (with opposing sides indicated at 211A and 211B) formed in the Ga₂O₃ epitaxial layer of the Ga₂O₃ base 202. While three interior trenches 211A-211C are depicted, it should be understood that more or less interior trenches may be formed in accordance with embodiments of the invention. Ga flux etching may result in residual droplets of Ga on surfaces of the device, as represented at 212.

As part of the exemplary photolithography process of step 102, portions of the SiO₂ mask 206 that remain after the Ga flux etching step are removed using BOE, resulting in a patterned Ga₂O₃ base 202 with trenches 210A-210C, and 211 formed therein. See FIG. 2C discussed below.

FIG. 2C is a cross-sectional side view of a stage 200C of a device of the present invention after the residual portions of SiO₂ mask 206 are removed.

As part of the exemplary photolithography process of step 102, the patterned Ga₂O₃ base 202 is soaked in hydrogen chloride (HCl) diluted in water (H₂O), to remove any remaining Ga droplets from surfaces of the Ga₂O₃ base 202. In implementations, the dilution ratio of H₂O to HCl utilized is 10:1. The patterned Ga₂O₃ base 202 is re-patterned with another photoresist, resulting in a repatterned Ga₂O₃ base 202 including trenches 210A-210C, 211A and 211B formed therein.

At 103, nickel oxide (NiO) (a p-type material) is deposited into trenches 210A-210B and 211 of the repatterned Ga₂O₃ base 202, thereby creating NiO trench regions 214A-214C, 215A and 215B within the repatterned Ga₂O₃ base 202. See FIG. 2D discussed below. In implementations, the NiO is deposited via sputtering from an NiO target, with a hole concentration (N_{A}) of N_{A}>10¹⁸ cm⁻³. The photoresist may then be removed using existing photolithographic techniques.

FIG. 2D is a cross-sectional side view of a stage 200D of a device of the present invention with NiO-filled interior trenches 214A-214C and an NiO-filled peripheral trench 215 (opposing portions of which are shown at 215A and 215B). As noted above, the number of interior trenches is not meant to be limited to the examples herein.

With reference back to FIG. 1, at 104, at least one junction termination extension (JTE) structure 217 is deposited about the periphery of the Ga₂O₃ base 202. In general, a JTE is a technique that improves the control of electric fields in p-n junctions. JTEs can be employed to reduce field crowding at a junction periphery where the charge in the JTE is designed to sink the critical electric field lines at breakdown.

FIG. 2E is a cross-sectional side view of a stage of a device of the present invention including a JTE 217 extending about the periphery of the device. In the embodiments of FIG. 2E, a first layer 216 of a bi-layer NiO JTE structure 217 is deposited on the Ga₂O₃ base 202 over portions of the peripheral NiO-filled trench 215 (e.g., portions of 215A and 215B) and portions of a surface of the Ga₂O₃ epitaxial layer 204. In implementations, the first layer 216 comprises 700 nanometers (nm) of NiO sputtered in a pure argon (Ar) atmosphere, resulting in a N_{A} of about 3×10¹⁷ cm⁻³. In embodiments, the first layer 216 is configured to extend beyond (e.g., ˜40 micrometers beyond) a respective edge of an anode contact 220. See FIG. 2E discussed below, for example.

In this first embodiment, a second layer 218 of the bi-layer NiO JTE structure 217 is then deposited over the first layer 216 and portions of the peripheral NiO-filled trench 215 (see portions of 215A, 215B covered by the bi-layer NiO JTE structure 217. In implementations, the second layer 218 is deposited in two stages.

FIG. 2F is a close-up partial view of FIG. 2F, including the two stages of the second bi-layer of the NiO JTE structure. Stage one is depicted in FIG. 2F at 219A and stage two is depicted in FIG. 2F at 219B, for example. In embodiments, the first stage comprises 250 nm of NiO in a 20:1 argon:oxygen (Ar:O₂) atmosphere followed by a second stage comprising 100 nm of NiO in a 2:1 Ar:O₂ atmosphere, resulting in an N_{A}>10¹⁹ cm⁻³.

FIG. 2G is a cross-sectional side view of an alternative embodiment 200G of a device of the present invention including a single layer JTE 217′. In implementations, the JTE structure 217′ comprises NiO deposited about the periphery of the Ga₂O₃ base 202. Opposing side portions 217A′ and 217B′ of the JTE 217′ are visible in FIG. 2G. More specifically, the JTE structure 217′ is deposited about the periphery of the Ga₂O₃ base 202 over portions of the peripheral NiO-filled trench 215 and portions of a surface of the Ga₂O₃ epitaxial layer 204.

FIG. 2H is a top view of the embodiments 200G of FIG. 2G. Note the JTE structure 217′ extends about the periphery of the semiconductor base 202.

With reference back to FIG. 1, at 105, an anode 220 (e.g., a platinum oxide (PtOₓ) and gold (Au) anode) is deposited over the interior NiO-filled trenches 214A-214C, over portions of the NiO-filled peripheral trench 215, and over portions of the JTE (e.g., over at least a portion of the second layer 218 of the NiO JTE 217), via reactive ion sputtering. See FIGS. 2E and 2F. Sec also the embodiment of FIG. 2G, wherein an anode 220′ is deposited over the interior NiO-filled trenches 214A-214C, over portions of the NiO-filled peripheral trench 215, and over portions of the JTE 217′. In implementations, the sputtering occurs from a platinum target at 3 mTorr, 50 W in a 10:4 Ar:O₂ atmosphere.

Returning to FIG. 1, at 106, a backside ohmic contact 222 (e.g., a nickel (Ni) and gold (Au) contact) is deposited onto a surface of the Ga₂O₃ substrate 203 via reactive ion sputtering, resulting in a Ga₂O₃—NiO heterojunction device 200E. In implementations, the sputtering occurs from a platinum target at 3 mTorr, 50W in a 10:4 Ar:O2 atmosphere. See FIGS. 2E, 2F and 2G discussed below.

At 107, the Ga₂O₃—NiO heterojunction device (e.g., 200E or 200G) is annealed. In implementations, the annealing is performed at 275° C. in nitrogen gas (N₂) for 15 minutes.

### Experimental Results

Fabrication of a PtOₓ-anode MPS device including Ni-anode JBS and reference PtOx and Ni anode SBDs was carried out on a Ga₂O₃ base comprised of a (001) oriented Sn-doped Ga₂O₃ substrate with a 5 μm thick halide vapor phase epitaxial (HVPE) epilayer with an unintentional Si doping concentration of 5×10¹⁶ moles per cubic centimeter (cm⁻³). The fabrication process began with a 100 nm PECVD SiO₂ mask deposited onto the Ga₂O₃ base and patterned using buffered oxide etchant (BOE). Atomic Ga flux etching was performed for 159 minutes (min) in a molecular beam epitaxy (MBE) reactor using a Ga flux at a pressure of ˜1.24×10⁻⁷ Torr and at thermocouple temperature of 725 degrees Celsius (° C.). Prior to Ga-flux etching, the SiO₂ patterned Ga₂O₃ surface was heat cleaned for 10 min at 800° C. The MBE reactor pressure was maintained at 1×10⁻⁹ Torr during the etching. BOE was used to remove the SiO₂ mask that remained after etching, followed by a 2 min soak in dilute 10:1 H2O:HCl to remove remaining Ga droplets from the surface of the Ga₂O₃ base. Profilometry using a scanning electron microscopy (SEM) yielded an etch depth of ˜240 nm for an etch rate of ˜1.51 nm/min. After re-patterning for NiO liftoff, ˜240 nm of NiO with a hole concentration N_{A}>10¹⁸ cm⁻³ was sputtered from a NiO target into the etched trenches. The room temperature sputtering conditions were 20:1 Ar:O₂, at 100 W power, and at a 3 mTorr pressure. Subsequently, a bi-layer NiO junction termination extension (JTE) was sputtered around the devices extending to ˜40 μm beyond the edge of an anode contact position.

The first JTE layer consisted of 700 nm of NiO sputtered in a pure Ar atmosphere, resulting in hole concentration N_{A} of about 3×10¹⁷ cm⁻³. The second JTE layer was sputtered in two parts consisting of 250 nm of 20:1 Ar:O₂ NiO followed by 100 nm of 2:1 Ar:O₂ NiO with N_{A}>10¹⁹ cm⁻³. All sputtering conditions, including the sputtered PtOₓ anode layer are listed in Table 1 below.

TABLE 1
Sputtering Conditions

| | | Thickness | Pressure | | |
|---|---|---|---|---|---|
| | Ar/O₂ | (nm) | (mTorr) | Power (W) | N_{A} (cm⁻³) |
| JBS NiO | 20:1 | 240 | 3 | 100 | >10¹⁸ |
| JTE 1 | 60:0 | 700 | 3 | 100 | ~3 × 10¹⁷ |
| JTE2 | 20:1 | 350 | 3 | 100 | >10¹⁸ |
| | 2:1 | 110 | 3 | 100 | >10¹⁹ |
| PtOₓ | 10:4 | 20 | 3 | 50 | — |

A schematic of the bi-layer JTE and the etched trench geometry is shown in FIG. 2E. The Ni/Au and PtOₓ/Au anodes were deposited via electron beam evaporation and reactive ion sputtering, respectively. Platinum oxide was sputtered from a platinum target (3 mTorr, 50 W) in a 10:4 Ar:O₂ atmosphere. Backside Ohmic contacts of Ti/Au (20/200 nm) were deposited using electron beam evaporation. The anode area was roughly 100×100 μm with rounded corners of radius 10 μm. A backside Ohmic contact anneal was not performed. Lastly, an anneal of the as-fabricated device structures was performed at 275° C. in N₂ for 15 min.

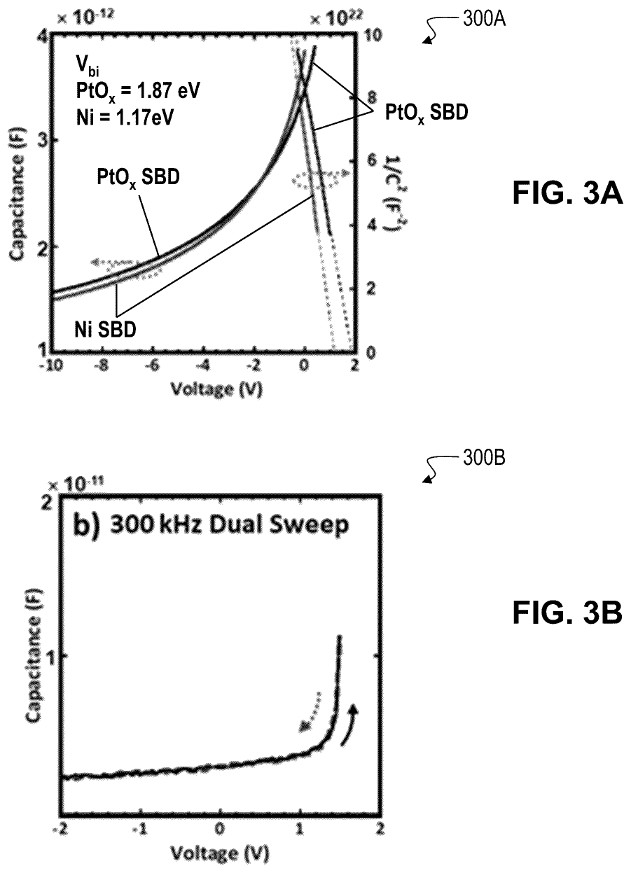

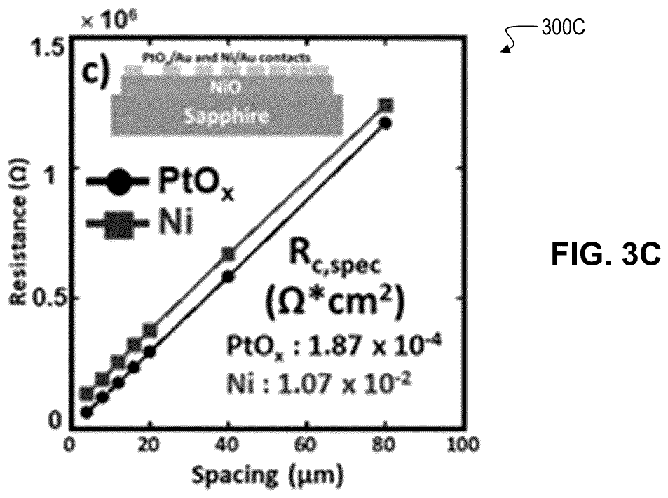

FIG. 3A is a chart 300A depicting C-V measurements of a PtOₓ and Ni SBD in accordance with embodiments of the invention. Capacitance-voltage (C-V) measurements were taken at 1 MHz frequency on the reference SBDs of both Ni and PtOₓ anodes to extract the Φ_{B,CV} as shown in FIG. 3A. The built-in potential (V_{bi}) for the Ni and PtOₓ anode metals was 1.17 eV and 1.87 eV, respectively. Using the extracted V_{bi} and the additional E_{C}-E_{F}, the Φ_{B,CV} was calculated to be 1.22 eV (Ni) and 1.92 cV (PtOₓ).

FIG. 3B is a chart 300B depicting C-V measurements of a PtOₓ JBS diode in accordance with embodiments of the invention, showing a dual sweep at 300 kHz measured from accumulation to depletion (dashed line) and back to accumulation (solid line). The absence of hysteresis shows that charge trapping along the etched sidewalls is minimal for the plasma-free etched Ga₂O₃ NiO heterojunction. As the JBS and MPS diodes were fabricated using identical mask designs, the differentiation between the two diode architectures stems from the Ohmic contact formation to the p+ NiO regions. The forward bias operation of a JBS diodes is determined mainly by majority carrier injection from the Schottky anode into the n-drift region. Since minority carrier injection from the p-region is not required, the anode does not need to form an Ohmic contact to the p-type NiO in a JBS diode. An improved Ohmic contact to the p-type region is necessary for the formation of a MPS diode where a second turn-on and increase in current density due to minority carrier injection occurs as the PN diode portion of the device turns on. In this work, the Ni and PtOₓ Ohmic contacts to p-NiO were evaluated using linear transmission line measurements (LTLM).

FIG. 3C is a chart 300C depicting linear transmission line measurements of Ni and PtOₓ Ohmic contacts to NiO. Control films of NiO were isolated via lift-off on sapphire substrates, as indicated in FIG. 3C. A specific contact resistance (R_{c,sp}) of 1.07×10⁻² Ω*cm² was extracted from the Ni/NiO LTLMs. The PtOₓ/NiO LTLMs resulted in a R_{c,sp} of 1.87×10⁻⁴ Ω*cm², a reduction of nearly two orders of magnitude. Similar sheet resistance values of 1.38×10⁶ Ω/sq (Ni) and 1.46×10⁶ Ω/sq (PtOₓ) where extracted as evidenced by the nearly linear slope of the LTLM data in FIG. 3C.

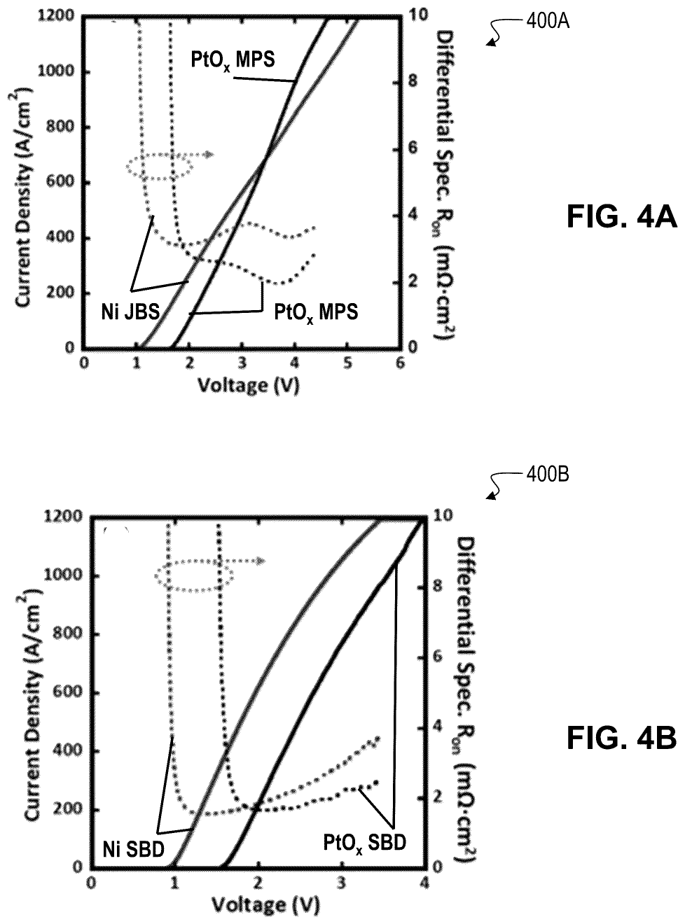

FIG. 4A is a chart 400A depicting C-V measurements for a PtOₓ MPS and Ni JBS diodes in accordance with embodiments of the invention. The forward current density voltage (J-V) characteristics were recorded using a Keithley 4200SCS source measurement unit. The JBS and MPS diodes can be analyzed by splitting the J-V characteristics into two regimes, a Schottky barrier regime (V_{F}<3V) and a PN diode regime (V_{F}>3V). The V_{F} value of 3 V is chosen due to the band-alignment of the Ga₂O₃ NiO heterojunction. The turn-on voltage (Vₒₙ) of the Ni/Au JBS diode was 1.13 V as shown in FIG. 4A. The minimum differential specific on-resistance (R_{on,sp}) of 3.12 mΩ·cm² occurred at V_{F} of 1.84 V. The differential R_{on,sp} showed a gradual increase as the JBS diode entered the PN regime where a minimum R_{on,sp} of 3.15 mΩ·cm² occurred at V_{F} of 5.18 V. The PtOₓ/Au MPS diode exhibits differing J-V/R_{on,sp} characteristics as shown in FIG. 4A. As a result of the increased PB of the PtOₓ anode compared to Ni, the PtOₓ MPS diode shows an increased Vₒₙ of 1.74 V. As the MPS diode turns on in the Schottky regime, the differential R_{on,sp} continuously decreases unlike the Ni JBS diode. A more drastic decrease of the R_{on,sp} is observed within the PN regime, where minimum value of 1.97 mΩ·cm² was observed at 3.7 V. It is at this point the improved Ohmic contact to PtOₓ/NiO results in a second turn-on and a higher current density compared to the Ni JBS diode. Increased forward current under surge conditions is a fundamental characteristic of a MPS diode due to minority carrier injection in these devices. Such behavior has not been reported for Ga₂O₃ devices before.

FIG. 4B is a chart 400B depicting C-V measurements Ni/Au and PtOₓ/Au SBDs in accordance with embodiments of the invention, showing a dual sweep at 300 kHz measured from accumulation to depletion and back to accumulation. Ni/Au and PtOₓ/Au SBDs were measured for comparison and exhibit a Vₒₙ of 0.97 V and 1.62 V, respectively, as depicted in FIG. 4B. The minimum differential R_{on,sp} of the Ni/Au SBD is 1.54 mΩ·cm² and increases beyond this point, similar to Schottky regime of the Ni/Au JBS diode. The PtOₓ/Au SBD has minimum differential R_{on,sp} of 1.67 mΩ·cm² with a less gradual increase beyond this point.

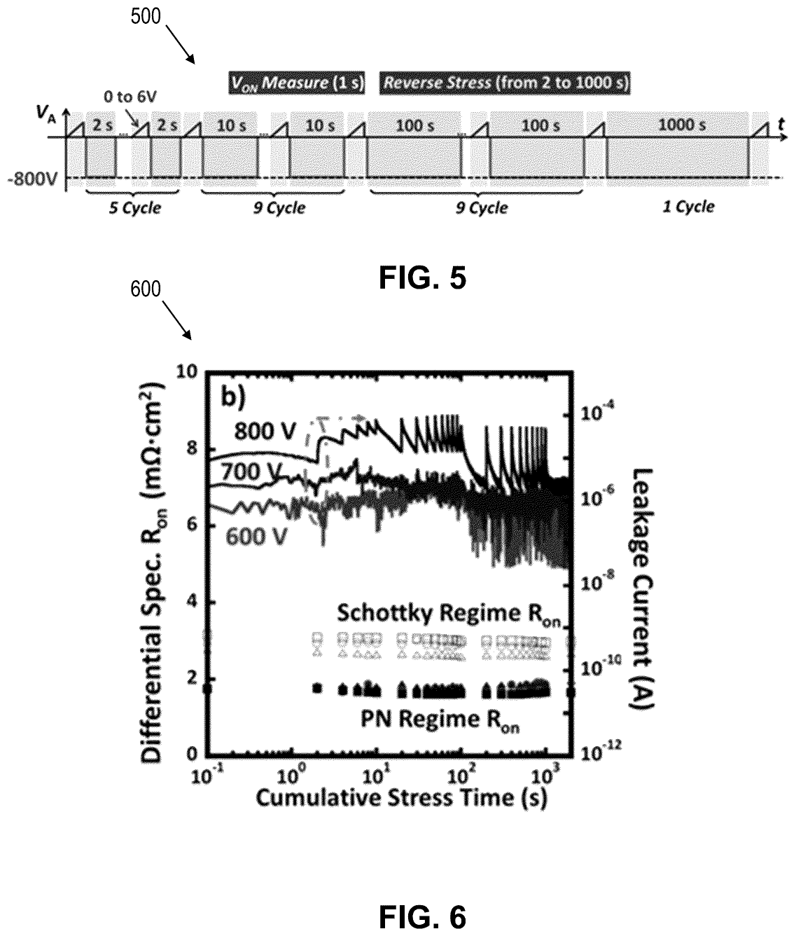

FIG. 5 illustrates a testing waveform 500 for high voltage reliability measurements in accordance with embodiments of the invention. Reverse I-V characteristics were measured in Fluorinert (FC70) using a Keithly 2657 as shown in FIG. 5. The PtOₓ MPS diode achieved a breakdown voltage (V_{BR}) of 1 kV while exhibiting a reduction in leakage current as a result of the increased PtOₓ Φ_{B} compared to Ni/Au JBS devices. A significant increase in leakage current was observed for the Ni/Au JBS devices, particularly at lower voltages, while achieving a V_{BR} of 900 V. The leakage current of the PtOₓ/Au SBD was comparable or slightly lower than the Ni/Au JBS devices up to 600 V. Current compliance of 100 μA was reached at 800 V for the PtOₓ SBD. The geometry or cell pitch, along with the abrupt junction doping concentrations of a JBS and MPS diode heavily influence the leakage current. The 6 μm pitch (4 μm Schottky and 2 μm Ohmic) of the JBS and MPS diodes is not ideal for this NiO Ga₂O₃ junction doping of N_{A}=˜10¹⁸ cm⁻³ and N_{D}=5×10¹⁸ cm⁻³, respectively. Further optimization of the cell pitch and geometry, as well as an increase in the abrupt junction doping profile could improve the leakage current without impacting the forward characteristics of the device.

A key advantage provided by the MPS (and JBS) diode structure, in accordance with embodiments of the invention, is the reduction of leakage current at the Schottky metal-semiconductor interface, a weak point of the device. Silvaco TCAD simulations for the PtOₓ MPS diode and SBDs were performed at an 800 V reverse bias. The peak electric field (E_{C}) 100 nm below the semiconductor interface showed a value of 3.22 MV/cm and 3.63 MV/cm for the MPS and SBDs, respectively. While only 0.4 MV/cm, the simulated reduction in peak E_{C} from the drift layer depletion was validated by the improved V_{BR} and leakage current from the experimental reverse I-V data.

Lastly, high bias reliability and stress testing were performed on the PtOₓ MPS diodes in accordance with embodiments of the invention, using a Keysight B1505. High bias reliability testing of Ga₂O₃ devices has not been reported in the literature to date and is a crucial test for evaluating the ruggedness and switching capabilities of Ga₂O₃. The testing waveform of the MPS diode according to embodiments of the invention is shown in FIG. 5. Device forward characteristics were initially measured before applying a maximum 800 V reverse bias for a cumulative stress time of 2000 s. Throughout the duration of the test, devices were periodically switched on a total of 25 times.

FIG. 6 is a chart 600 depicting specific on-resistance and reverse leakage current as a function of stress time measured at 600, 700 and 800 V. During the test, each time the MPS diode was periodically switched on, the minimum differential R_{on,sp} was recorded within the Schottky and PN regime. Analysis of the R_{on,sp} values shows minimal variation (˜0.1 mΩ·cm²), remaining nearly constant throughout the duration of each 2000 s measurement.

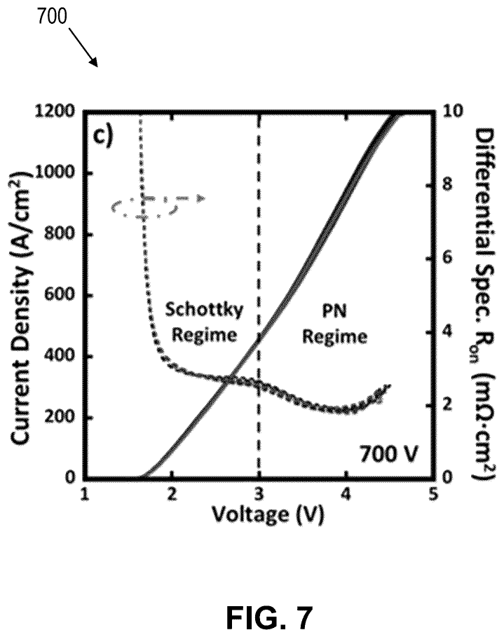

FIG. 7 is a chart 700 depicting forward J-V measurements (25 curves) taken during the reliability measurements of the MPS diode at 700V. The vertical dashed line separates the Schottky and PN regimes of the MPS diode. The forward J-V characteristics are plotted for each device turn-on that occurred during the 700 V reliability test, as depicted in FIG. 7. The nearly identical Vₒₙ and R_{on,sp} within the Schottky regime of the MPS diode further supports a lack of charge trapping at the plasma-etch-free interface contributing to excellent diode stability.

In conclusion, fabrication of Ga₂O₃ NiO heterojunction devices using a plasma-etch-free Ga flux etch method was demonstrated. MPS and JBS diodes were fabricated utilizing PtOₓ and Ni contacts, respectively. An increased metal work function provides a larger Schottky barrier height to the n-type Ga₂O₃ for improved leakage current while simultaneously improving the Ohmic contact to p-type NiO. Analysis of the NiO Ohmic contacts shows that PtOₓ has a lower R_{c,sp} compared to Ni. The improved contact resistance results in a significant reduction of the R_{on,sp} and an increase of the current density as the PN diode portion of the MPS diode of the present invention is switched on, a trait not exhibited by the Ni JBS diodes.

The PtOₓ MPS diodes fabricated in accordance with embodiments of the invention achieved a V_{BR} of 1 kV while also withstanding 800 V reliability testing for a cumulative time of 2000 s. The quality of the etched surface and lack of charge trapping at the heterojunction is supported by the nearly constant turn-on characteristics of the MPS diodes.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method of making a gallium oxide (Ga₂O₃)-nickel oxide (NiO) heterojunction device comprising:
providing a Ga₂O₃ base including a Ga₂O₃ substrate with an n-type Ga₂O₃ epitaxial layer thereon;
forming NiO-filled internal trenches and an NiO-filled peripheral trench in the n-type Ga₂O₃ epitaxial layer using a plasma-free etching process;
forming at least one junction termination extension (JTE) structure about the periphery of the n-type Ga₂O₃ epitaxial layer;
depositing an anode over the NiO filled interior trenches, over portions of the NiO-filled peripheral trench, and over portions of the JTE structure; and
depositing a cathode over a bottom surface of the Ga₂O₃ substrate, thereby forming the Ga₂O₃—NiO heterojunction device, wherein the Ga₂O₃—NiO heterojunction device is formed without the use of plasma-etching and is free of plasma-etching damage.

2. The method of claim 1, wherein forming the NiO-filled internal trenches and an NiO-filled peripheral trench includes:
forming internal trenches in the n-type Ga₂O₃ epitaxial layer via the plasma-free etching process;
forming a peripheral trench extending about the periphery of the n-type Ga₂O₃ epitaxial layer via the plasma-free etching process;
depositing p-type NiO into the internal trenches and the peripheral trench, thereby forming the NiO-filled internal trenches and an NiO-filled peripheral trench.

3. The method of claim 1, wherein forming the JTE structure comprises: depositing the at least one JTE structure over portions of the NiO filled peripheral trench and surface portions of the Ga₂O₃ epitaxial layer.

4. The method of claim 1, wherein the Ga₂O₃—NiO heterojunction device comprises a merged PiN Schottky (MPS) diode having a specific contact resistance between the anode and the NiO of less than 0.0005 Ohm*cm².

5. The method of claim 1, wherein the JTE structure comprises a bi-layer JTE structure including first and second layers of NiO.

6. The method of claim 5, wherein depositing the JTE structure comprises:
depositing a first layer of NiO via sputtering in a pure argon atmosphere over portions of the peripheral NiO-filled trench and over portions of a surface of the Ga₂O₃ epitaxial layer; and
depositing a first stage of a second layer of NiO in 20:1 argon:oxygen atmosphere over the first layer and portions of the peripheral NiO-filled trench; and
depositing a second stage of the second layer of NiO in a 2:1 argon:oxygen atmosphere over the first stage of the second layer of NiO and portions of the peripheral NiO-filled trench.

7. The method of claim 1, wherein the JTE structure comprises a layer of NiO.

8. The method of claim 1, wherein forming the NiO-filled internal trenches and the NiO-filled peripheral trench in the n-type Ga₂O₃ epitaxial layer using a plasma-free etching process comprises patterning using photolithography and gallium flux etching.

9. The method of claim 1, further comprising annealing the Ga₂O₃—NiO heterojunction device.

10. The method of claim 1, wherein the anode and cathode comprise platinum oxide and gold.

11. The method of claim 1, wherein the n-type Ga₂O₃ epitaxial layer is doped with silicon (Si).

12. A gallium oxide (Ga₂O₃)-nickel oxide (NiO) heterojunction device comprising:
a Ga₂O₃ base comprised of a Ga₂O₃ substrate with an n-type Ga₂O₃ epitaxial layer thereon, the n-type Ga₂O₃ epitaxial layer including a plurality of NiO-filled internal trenches and an NiO-filled peripheral trench;
a junction termination extension (JTE) structure formed about the periphery of the n-type Ga₂O₃ epitaxial layer;
an anode formed over the NiO filled interior trenches, over portions of the NiO-filled peripheral trench, and over portions of the JTE structure; and
a cathode formed over a bottom surface of the Ga₂O₃ substrate, wherein the Ga₂O₃—NiO heterojunction device is formed without the use of plasma-etching and is free of plasma-etching damage.

13. The Ga₂O₃—NiO heterojunction device of claim 12, wherein the JTE structure is a NiO bi-layer JTE structure.

14. The Ga₂O₃—NiO heterojunction device of claim 13, wherein the first layer of the NiO bi-layer JTE structure extends beyond opposing edges of the anode.

15. The Ga₂O₃—NiO heterojunction device of claim 12, wherein the JTE structure comprises a layer of NiO.

16. The Ga₂O₃—NiO heterojunction device of claim 12, wherein the anode and cathode comprise platinum oxide and gold.

17. The Ga₂O₃—NiO heterojunction device of claim 12, wherein the JTE structure is formed over portions of the NiO filled peripheral trench and surface portions of the Ga₂O₃ epitaxial layer.

18. The Ga₂O₃—NiO heterojunction device of claim 12, wherein the Ga₂O₃—NiO heterojunction device comprises a merged PiN Schottky (MPS) diode having a specific contact resistance between the anode and the NiO of less than 0.0005 Ohm*cm².

19. The Ga₂O₃—NiO heterojunction device of claim 12, wherein the n-type Ga₂O₃ epitaxial layer is doped with silicon (Si).

20. The Ga₂O₃—NiO heterojunction device of claim 12, wherein the n-type Ga₂O₃ epitaxial layer has a thickness of at least 5 microns.
